(19) United States
(12) Patent Application Publication
(10) Pub. No.: US 2012/0212432 A1
(43) Pub. Date: Aug. 23, 2012

(54) TOUCH PANEL AND METHOD FOR MANUFACTURING OF THE SAME

(75) Inventors: Keishiro Murata, Kyoto (JP); Kenichi Matsumoto, Oaska (JP)

(73) Assignee: Panasonic Corporation, Osaka (JP)

(21) Appl. No.: 13/370,416

(22) Filed: Feb. 10, 2012

(30) Foreign Application Priority Data
Feb. 22, 2011 (JP) JP 2011-035645

(51) Int. Cl. G06F 3/041; H05K 13/00

(52) U.S. Cl. 345/173; 29/592.1

(57) ABSTRACT

A touch panel has a first substrate, a second substrate, plural first conductive layers, plural second conductive layers, plural first electrodes, and plural second electrodes. The first conductive layers have substantially strip-shapes, and are arrayed on a first surface of the first substrate in the first direction, while extending in a second direction orthogonal to the first direction. The plural first electrodes are buried in the first surface of the first substrate, and one ends thereof are connected to the plural first conductive layers, respectively. The second substrate is arranged as opposed to the first surface. The plural second conductive layers are opposed to the plural first conductive layers, and are arrayed in the second direction while extending in the first direction. One ends of the plural second electrodes are connected to the plural second conductive layers, respectively.

### BACKGROUND OF THE INVENTION

1. Field of the Invention

The present invention relates to a touch panel and method for manufacturing of the same used primarily for operation of various electronic equipment.

2. Description of the Related Art

In recent years, various electronic equipment, such as mobile phones and electronic cameras, are becoming more multifunctional and diversified, and the number of various electronic equipment operable by means of a touch panel is on the increase. For example, in electronic equipment where an optically transparent touch panel is mounted on an upper surface of a display element such as a liquid crystal display element, it is possible to bring the touch panel into an operation with a finger or the like, while viewing through the touch panel a display of the display element on the rear surface of the touch panel. There is an increase in number of electronic equipment capable of switching various functions by means of such a touching operation, and there has been required electronic equipment easy to view and reliably operable.

A conventional touch panel provided to such electronic equipment will be described with reference to FIGS. 7 and 8. It is to be noted that these figures are partially expanded in size in order to facilitate understanding of a configuration.

FIG. 7 shows an exploded perspective view of conventional touch panel 50, and FIG. 8 shows a sectional view along line 8-8 of conventional touch panel 50 shown in FIG. 7. In FIGS. 7 and 8, touch panel 50 has upper substrate 1, upper conductive layers 26, upper electrodes 3, lower substrate 4, lower conductive layers 27, lower electrodes 6, and cover substrate 7. Upper substrate 1 and lower substrate 4 are shaped in film form and have optical transparency. Upper conductive layers 26 and lower conductive layers 27 are made of indium tin oxide or the like, and shaped in substantially strip-shaped, and have optical transparency. Upper electrodes 3 and lower electrodes 6 are conductive bodies made of silver, carbon or the like.

On the upper surface of upper substrate 1, plural upper conductive layers 26 are formed as arrayed in a longitudinal direction at predetermined intervals, and as extended in a horizontal direction orthogonal to the longitudinal direction. One ends of upper electrodes 3 are connected to respective end sections of plural upper conductive layers 26, and the other ends of upper electrodes 3 are formed extending to the front end along the outer periphery of upper substrate 1.

Further, on the upper surface of lower substrate 4, plural lower conductive layers 27 are formed as arrayed in the horizontal direction at predetermined intervals, and as extended in the longitudinal direction. One ends of lower electrodes 6 are connected to respective end sections of plural lower conductive layers 27, and the other ends of lower electrodes 6 are formed extending from the lower substrate 4 to the front end.

Cover substrate 7 is shaped in film form and has optical transparency. Upper substrate 1 is superimposed on the upper surface of lower substrate 4, and cover substrate 7 is superimposed on the upper surface of upper substrate 1. These substrates are pasted to each other by means of adhesive layers 28, 29, to configure touch panel 50.

Touch panel 50 as thus configured is arranged on an upper surface of a display element such as a liquid crystal display element, to be mounted in the electronic equipment. Plural upper electrodes 3 and lower electrodes 6, extended to the front end, are electrically connected to an electronic circuit of the electronic equipment through a flexible wiring substrate, a connector or the like. As shown in FIG. 8, panel member 30 which is mounted to a housing of the electronic equipment and which is made of transparent or translucent material, such as plastic or glass, is provided above touch panel 50.

In the above configuration, a voltage is applied sequentially from the electronic circuit to plural upper electrodes 3 and lower electrodes 6. When the user touches an upper surface of a panel member 30 with his or her finger or the like to perform an operation in accordance with a display of a display element on the rear surface of the touch panel, respective capacitances of upper conductive layer 26 and lower conductive layer 27 in this operated place change. The electronic circuit detects the operated place based on this change in the capacitances, to switch various functions of the electronic equipment.

For example, with plural menus and the like being displayed on the display element on the rear surface, the upper surface of panel member 30 on a desired menu is touched with the user's finger or the like. Then, respective capacitances of upper conductive layer 26 and lower conductive layer 27 of the touch panel in the operated place change. These changes in capacitances are detected by the electronic circuit, to perform selection of a desired menu, and the like.

The formation of smaller widths of and intervals between plural upper electrodes 3 and lower electrodes 6, particularly smaller widths of and intervals between plural upper electrodes 3 that extend from the outer periphery of upper substrate 1 to the front end, so called narrow pitching, is sought for the purpose of overall size reduction. Plural upper electrodes 3 protruded and formed on the upper surface of upper substrate 1 by printing or the like typically have heights of about 0.005 mm to 0.02 mm. For that reason, when widths of and intervals between the electrodes are made excessively small, at the time of pasting cover substrate 7 to the upper surface of upper substrate 1 by means of adhesive layer 29, plural bubbles 10 may be generated inside adhesive layer 29 between plural upper electrodes 3 as shown in FIG. 8. These plural bubbles 10 make the display element on the rear surface poorly viewable for the user.

In order to prevent generation of such bubbles 10 that inhibit viewability, plural upper electrodes 3 are typically formed in large size, having widths of about 0.2 mm to 0.3 mm and intervals of about 0.4 mm to 0.6 mm.

For example, a touch panel similar to such touch panel 50 is disclosed in Unexamined Japanese Patent Publication No. 2009-93397.

### SUMMARY OF THE INVENTION

A touch panel has a first substrate, a second substrate, plural first conductive layers, plural second conductive layers, plural first electrodes, and plural second electrodes. The first conductive layers have strip-shapes on a first surface of the first substrate, and are arrayed in a first direction, while extending in a second direction orthogonal to the first direction. The plural first electrodes are buried in the first surface of the first substrate, and have one ends connected to the plural first conductive layers, respectively. The second substrate is opposed to the first surface. The plural second conductive layers are opposed to the plural first conductive layers, and are arrayed in the second direction while extending in the first direction. The plural second electrodes have one ends connected to the plural second conductive layers, respectively. This touch panel does not inhibit viewability of a display element provided on the rear surface of the touch panel, and it is thus possible to seek narrow pitching of the plural first electrodes and plural second electrodes as well as overall size reduction, and it is also possible for the user to readily view the display element on the rear surface, so as to perform a reliable operation.

### BRIEF DESCRIPTION OF DRAWINGS

FIG. 1 shows an exploded perspective view of a touch panel in a first exemplary embodiment of the present invention;

FIG. 2 shows a sectional view along line 2-2 of the touch panel shown in FIG. 1;

FIG. 3A shows a partial sectional view of a manufacturing process for the touch panel in the first exemplary embodiment of the present invention;

FIG. 3B shows a partial sectional view of the manufacturing process for the touch panel in the first exemplary embodiment of the present invention;

FIG. 3C shows a partial sectional view of the manufacturing process for the touch panel in the first exemplary embodiment of the present invention;

FIG. 3D shows a partial sectional view of the manufacturing process for the touch panel in the first exemplary embodiment of the present invention;

FIG. 4 shows an exploded perspective view of the touch panel in the first exemplary embodiment of the present invention;

FIG. 5 shows an exploded perspective view of a touch panel in a second exemplary embodiment of the present invention;

FIG. 6 shows an exploded perspective view of the touch panel in the second exemplary embodiment of the present invention;

FIG. 7 shows an exploded perspective view of a conventional touch panel; and

FIG. 8 shows a sectional view along line 8-8 of the conventional touch panel shown in FIG. 7.

### DETAILED DESCRIPTION OF THE PREFERRED EMBODIMENT

### First Exemplary Embodiment

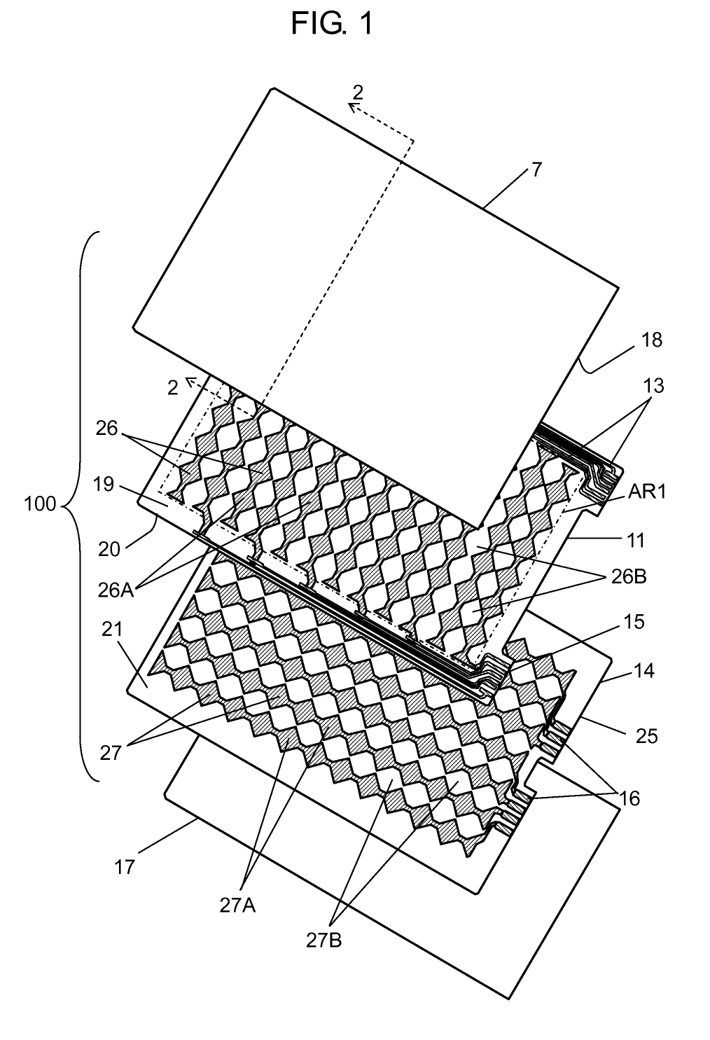

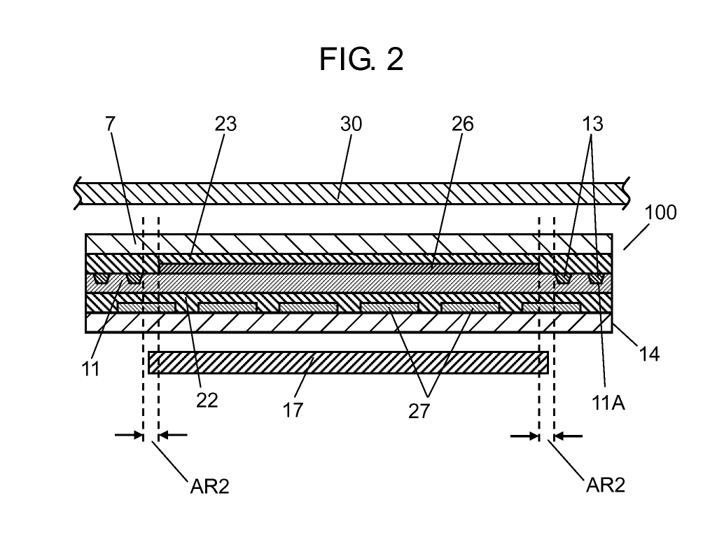

FIG. 1 shows an exploded perspective view of touch panel 100 in a first exemplary embodiment of the present invention, and FIG. 2 shows a sectional view along line 2-2 of touch panel 100 and a display element shown in FIG. 1. In FIGS. 1 and 2, touch panel 100 has upper substrate 11 as a first substrate, plural upper conductive layers 26 as plural first conductive layers, plural upper electrodes 13 as plural first electrodes, cover substrate 7 as a second substrate, lower substrate 14 as a third substrate, plural lower conductive layers 27 as plural second conductive layers, and plural lower electrodes 16 as plural second electrodes. Cover substrate 7 has lower surface 18 as a second surface. Upper substrate 11 has upper surface 19 as a first surface and lower surface 20 as a third surface. Lower substrate 14 has upper surface 21 as a fourth surface.

Upper substrate 11 and lower substrate 14 are made of polyethylene terephthalate, polyether sulfone, polycarbonate, or the like, and shaped in film form, and have optical transparency. Upper substrate 11 and lower substrate 14 are shaped in rectangular form with its longitudinal direction taken as the first direction. Upper conductive layers 26 and lower conductive layers 27 are made of indium tin oxide, tin oxide, or the like, and have a strip-shape, and have optical transparency. Upper electrodes 13 and lower electrodes 16 have strip-shapes, and conductive bodies made of silver, carbon or the like. In the embodiment, the “strip-shape” includes a substantially strip-shape having a non-uniform width and a curved shape.

On upper surface 19 of upper substrate 11, plural upper conductive layers 26 are arrayed in the first direction at predetermined intervals by means of sputtering or the like, and formed extending in a second direction orthogonal to the first direction. Upper substrate 11 has end section 15 in the first direction. One ends of upper electrodes 13 are connected to ends of upper conductive layers 26, and the other ends of upper electrodes 13 extend from the outer periphery of upper surface 19 of upper substrate 11 to end section 15. In the first exemplary embodiment, the outer periphery of upper surface 19 refers to an area around range AR1 made up of plural upper conductive layers 26, and between range AR1 and the outer edge of upper surface 19. Plural upper electrodes 13 extend from their respective one ends to the other ends in the first direction of the outer periphery of upper surface 19.

Plural thin groove sections 11A are formed on the outer periphery of upper surface 19 of upper substrate 11 in a position to be provided with plural upper electrodes 13, and plural upper electrodes 13 are buried and formed inside plural thin groove sections 11A.

On upper surface 21 of lower substrate 14, plural lower conductive layers 27 are arrayed in the second direction at predetermined intervals by means of sputtering or the like, and formed extending in the first direction. Lower substrate 14 has end section 25 in the first direction. One ends of plural lower electrodes 16 are connected to end sections of lower conductive layers 27, and the other ends of plural lower electrodes 16 are formed extending to end section 25 of lower substrate 14. Lower electrodes 16 are buried and formed inside thin groove sections provided on upper surface 21 of lower substrate 14.

In the first exemplary embodiment, the first direction refers to longitudinal directions of upper substrate 11 and lower substrate 14. When respective intervals between plural upper conductive layers 26 arrayed in the first direction and between plural lower conductive layers 27 arrayed in the second direction are made equivalent, as for the numbers of conductive layers provided on the respective substrates, the number of upper conductive layers 26 is larger than the number of lower conductive layer 27. That is, also as for the numbers of electrodes extracted from the respective conductive layers, the number of upper electrodes 13 is larger than the number of lower electrodes 16. For that reason, plural upper electrodes 13 are formed with narrower pitches than plural lower electrodes 16 on the outer peripheries.

Plural square sections 26A and plural square sections 27A are connected in strip-shaped, to form plural upper conductive layers 26 and plural lower conductive layers 27, respectively. Plural void sections 26B and 27B in substantially square shape are provided between these plural square sections. With upper substrate 11 and lower substrate 14 being in a superimposed state, plural square sections 26A in plural upper conductive layers 26 are formed so as to be vertically superimposed in an alternate manner in plural void sections 27B between plural square sections 27A in plural lower conductive layers 27. It is noted that the shape of plural square sections 26A of plural upper conductive layer 26 is not limited to the square shape, and the shape of plural square sections 27A of plural lower conductive layer 27 is not limited to the square shape.

Cover substrate 7 is made of polyethylene terephthalate or the like, and shaped in film form, and has optical transparency. Lower surface 20 of upper substrate 11 is superimposed on upper surface 21 of lower substrate 14, and lower surface 18 of cover substrate 7 is superimposed on upper surface 19 of upper substrate 11. These substrates are bonded to each other by means of adhesive layers 22 and 23 made of acrylic, rubber or the like, to configure touch panel 100.

As thus described, touch panel 100 of this first exemplary embodiment has the configuration where plural upper conductive layers 26 formed so as to be arrayed in the first direction and extend in the second direction, and plural lower conductive layers 27 formed so as to be arrayed in the second direction and extend in the first direction are arranged as opposed to each other at predetermined intervals via upper substrate 11.

Touch panel 100 as thus configured is arranged so as to face an upper surface of display element 17 such as a liquid crystal display element, to be mounted in electronic equipment. Plural upper electrodes 13 or lower electrodes 16, extended to end section 15 or end section 25 of upper substrate 11 or lower substrate 14, are electrically connected to the electronic circuit of the equipment via a flexible wiring substrate, a connector or the like. Then, as shown in FIG. 2, panel member 30 which is mounted to a housing of the electronic equipment and which is made of transparent or translucent material, such as plastic or glass, is provided above touch panel 100.

In FIG. 2, display element 17 is arranged so as to face the lower surface of lower substrate 14. Range AR2 is a range between the each of respective ends of plural upper conductive layers 26 and innermost upper electrode 13 out of plural upper electrodes 13. Display element 17 is arranged such that its end of an area displaying image is within range AR2. A figure of display element 17 in FIG. 2 indicates the area displaying image. A width of each of plural upper electrodes 13 is preferably as small as possible since the area displaying an image on display elements 17, that is, a display area, becomes large accordingly. With removing cover substrate 7, a lower surface of panel member 30 may adhere to adhesive layer 23.

In the above configuration, a voltage is sequentially applied to plural upper electrodes 13 and lower electrodes 16 by means of the electronic circuit. The user touches the upper surface of panel member 30 with his or her finger or the like to perform an operation in accordance with a display of display element 17 on the rear surface of touch panel 100. Touching or moving on the upper surface of panel member 30 with the finger or the like leads to a change in respective capacitances of upper conductive layer 26 and lower conductive layer 27 in the operated place. The electronic circuit detects the operated place based on this change in capacitance, to switch various functions of the electronic equipment.

For example, with plural menus and the like being displayed on display element 17, the upper surface of panel member 30 on a desired menu is touched by the user with his or her finger or the like. Then, respective capacitances of upper conductive layer 26 and lower conductive layer 27 of the touch panel in the operated place change. These changes in capacitances are detected by the electronic circuit, to perform selection of a desired menu, and the like.

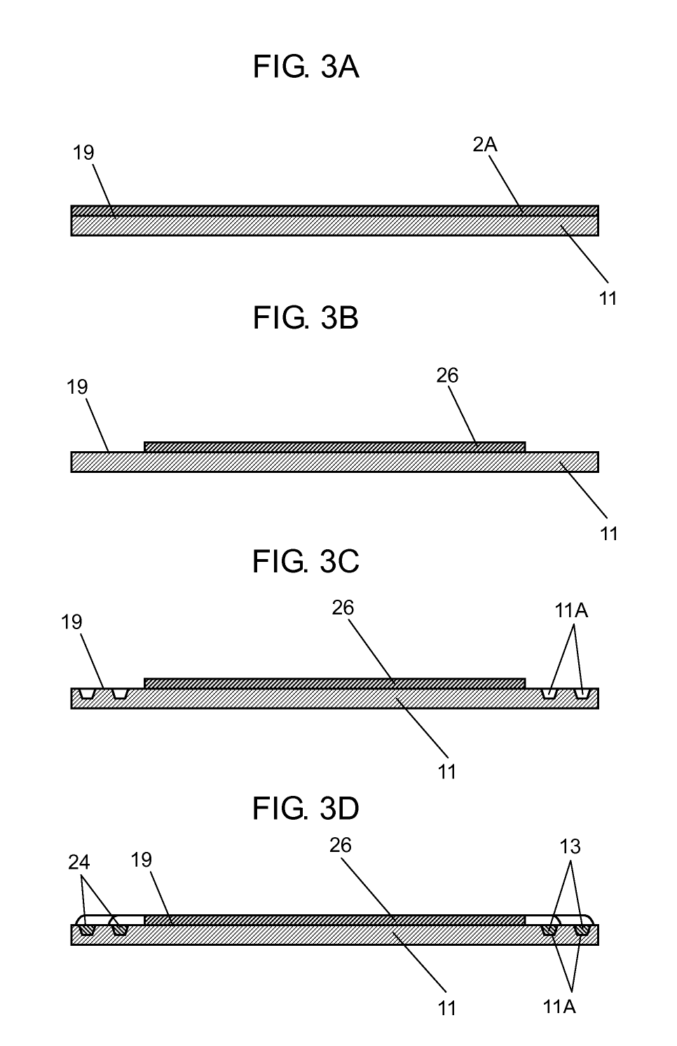

A description will be given of a method for manufacturing upper substrate 11 and lower substrate 14 of touch panel 100 as described above. FIGS. 3A to 3D show partial sectional views of a manufacturing process for a touch panel in the first exemplary embodiment of the present invention. For example, a process for manufacturing upper substrate 11 will be described. As shown in FIG. 3A, thin film 2A made of indium tin oxide or the like is laminated and formed over upper surface 19 of upper substrate 11. Then, as shown in FIG. 3B, thin film 2A is subjected to etching or the like to dissolved and remove an unnecessary area of thin film 2A so that plural upper conductive layers 26 having substantially strip shapes are formed on upper surface 19 of upper substrate 11.

Thereafter, as shown in FIG. 3C, plural thin groove sections 11A are formed on the outer periphery of upper surface 19 of upper substrate 11 by laser-cutting or the like. One ends of plural thin groove sections 11A are connected to ends of plural upper conductive layers 26, and the other ends thereof are extended from the outer periphery of upper substrate 11 to end section 15 (see FIG. 1). Depths of plural thin groove sections 11A are formed to be about 0.005 mm to 0.02 mm, and widths thereof be about 0.05 mm to 0.1 mm. Respective intervals between plural thin groove sections 11A are formed to be about 0.1 mm to 0.2 mm.

Next, as shown in FIG. 3D, plural upper electrodes 13 are buried and formed inside plural thin groove sections 11A on upper surface 19 of upper substrate 11. First, a conductive paste containing resin, such as epoxy or polyester, having conductive powder, such as silver powder or carbon powder, dispersed therein is applied into plural thin groove sections 11A and to the ends of upper conductive layers 26 by printing or using a dispenser, and then dried, to form plural upper electrodes 13. Thereby, respective one ends of plural upper electrodes 13 are connected to the respective end sections of plural upper conductive layers 26, and the respective other end sections of plural upper electrodes 13 are extended from the outer periphery of upper substrate 11 to end section 15. In such a manner, plural upper electrodes 13 are buried and formed inside upper substrate 11.

Lower substrate 14 is manufactured in a similar manner to upper substrate 11. As thus described, upper substrate 11 and lower substrate 14 are manufactured. Then, upper surface 19 of upper substrate 11 adheres to lower surface 18 of cover substrate 7 with adhesive layer 23, and upper surface 21 of lower substrate 14 adheres to lower surface 20 of upper substrate 11 with adhesive layer 22, to complete touch panel 100. An order of adhering is not restricted to the order described above.

As thus described, plural upper electrodes 13 and lower electrodes 16 are buried in upper substrate 11 and lower substrate 14 respectively. Upper substrate 11 and lower substrate 14 and cover substrate 7 are adhered with adhesive layer 22 and adhesive layer 23. In such a manner, upper electrodes 13 or lower electrodes 16 do not protrude on upper surface 19 of upper substrate 11 or upper surface 21 of lower substrate 14, and it is thus possible to prevent generation of bubbles or the like on areas formed upper electrodes 13 and lower electrodes 16.

That is, plural upper electrodes 13 and lower electrodes 16 are not protruded on upper surface 19 of upper substrate 11 or upper surface 21 of lower substrate 14 by printing or the like, but buried in upper substrate 11 and lower substrate 14 respectively. This can prevent generation of bubbles or the like between each of plural upper electrodes 13 or plural lower electrodes 16 when cover substrate 7 is adhered to upper substrate 11 or upper substrate 11 is adhered to lower substrate 14. Further, it is possible to seek narrow pitching of plural upper electrodes 13 and lower electrodes 16, in which respective widths of and intervals between those electrodes are formed to be small, so as to seek overall size reduction in touch panel 100.

At the time of causing upper substrate 11 to adhere to cover substrate 7, and causing lower substrate 14 to adhere to upper substrate 11, with adhesive layers 23 and 22 respectively, high pressure may be applied to the substrates in the bonded state, to remove bubbles. This can more reliably prevent generation of bubbles.

Plural upper electrodes 13 respectively have exposed surfaces 24 (see FIG. 3D) exposed from upper surface 19 of upper substrate 11. Exposed surface 24 is preferably flush with upper surface 19 of upper substrate 11. This can prevent generation of bubbles or the like, for example, between each of plural upper electrodes 13 or between each of plural upper electrodes 13 and each of the end sections of upper conductive layers 26 at the time of causing upper surface 19 of upper substrate 11 to adhere to lower surface 18 of cover substrate 7 by means of adhesive layer 23.

Similarly, an exposed surface of each of plural lower electrodes 16 exposed from upper surface 21 of lower substrate 14 is preferably flush with upper surface 21 of lower substrate 14. This can prevent generation of bubbles or the like, for example, between each of plural lower electrodes 16 or between each of plural lower electrodes 16 and each of the end sections of lower conductive layers 27 at the time of causing upper surface 21 of lower substrate 14 to adhere to lower surface 20 of upper substrate 11 with adhesive layer 22.

Further, in portions of upper surface 19 and upper surface 21 where the electrodes are buried, the roughness is small, and it is thereby possible to obtain the above effect according to the present invention whichever material adhesive layer 22 and adhesive layer 23 are made of.

Even in the case as thus described where plural upper electrodes 13 and plural lower electrodes 16 are formed in such a size of widths of about 0.05 to 0.1 mm and intervals of about 0.1 to 0.2 mm, bubbles or the like that inhibit viewability of a display of display element 17 tend not to be generated. This allows the user to readily view a display such as a menu on display element 17, so as to reliably perform an operation without an erroneous operation. Further, even when respective widths of and intervals between plural upper electrodes 13 and plural lower electrodes 16 are different from the foregoing sizes, a similar effect to the foregoing effect can be obtained by burying and forming these electrodes.

It is to be noted that the configuration was described above where both upper electrode 13 and lower electrode 16 are respectively buried in upper substrate 11 and lower substrate 14, but this is not restrictive. Depending on the number of electrodes and arrangement thereof, it may be configured such that only one of upper electrodes 13 and lower electrodes 16 are buried and formed inside the substrate, and the other electrodes are formed on the upper surface of the substrate by means of printing or the like. For example, plural upper electrodes 13, arranged with narrower pitches, may be buried in upper substrate 11, and plural lower electrodes 16 may not be buried in lower substrate 14. This can eliminate the need for the process step of forming the thin groove sections for burying of lower electrodes 16, so as to reduce the number of process steps.

Further, the configuration was described above where all of plural upper electrodes 13 provided on the outer periphery of upper substrate 11 or all of plural lower electrodes 16 provided on the outer periphery of lower substrate 14, or both of them, are buried, but this is not restrictive. For example, among plural upper electrodes 13 provided on the outer periphery of upper substrate 11, plural upper electrodes 13 located in the vicinities of the end sections of upper conductive layers 26 may be buried. Further, for example, among plural upper electrodes 13 provided on the outer periphery of upper substrate 11, only innermost upper electrode 13 may be buried.

As thus described, according to the first exemplary embodiment, at least one of plural upper electrodes 13 or lower electrodes 16 are buried and formed inside upper substrate 11 or lower substrate 14. One ends of plural upper electrodes 13 and lower electrodes 16 are respectively connected to upper conductive layers 26 or lower conductive layers 27, and the other ends thereof are extended to the outer periphery of upper substrate 11 or lower substrate 14. Thereby, bubbles or the like tend not to be generated between plural upper electrodes 13 or plural lower electrodes 16 at the time of pasting between cover substrate 7 and upper substrate 11, or between upper substrate 11 and lower substrate 14 by means of adhesive layer 22 or adhesive layer 23 or the like. In this manner, it is possible to obtain touch panel 100 in which narrow pitching of upper electrodes 13 and lower electrodes 16 as well as overall size reduction can be sought, and the user can readily view a display of display element 17 so as to perform a reliable operation.

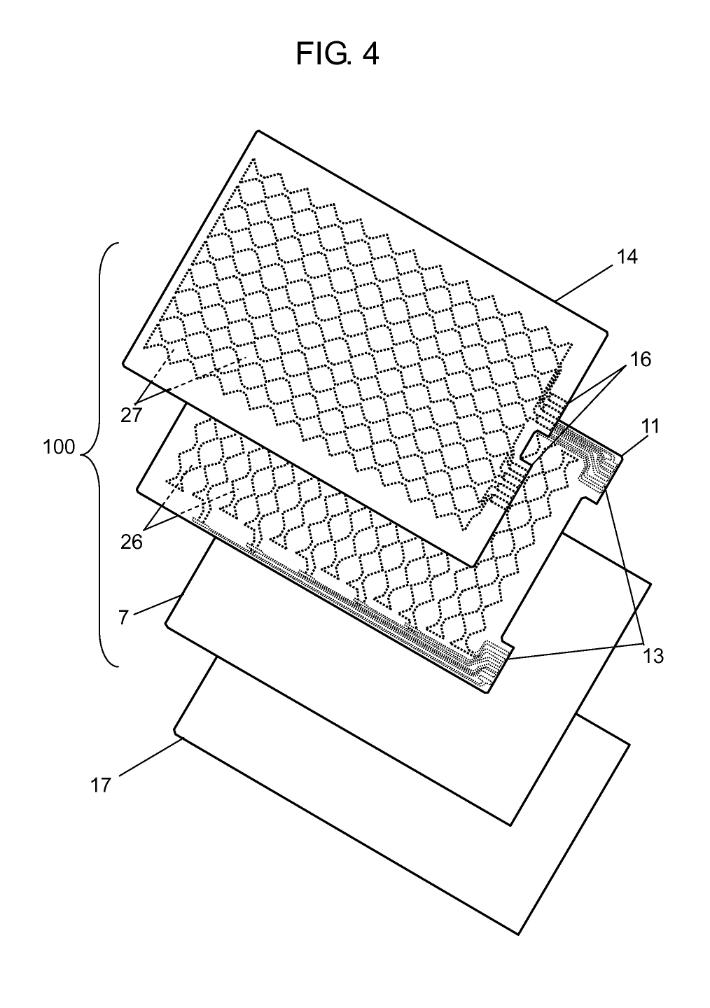

It should be noted that, although display element 17 is provided below lower substrate 14 in the first exemplary embodiment, display element 17 may be provided above cover substrate 7. FIG. 4 shows an exploded perspective view of touch panel 100 in the first exemplary embodiment. FIG.4 corresponds to a view from below touch panel 100 shown in FIG. 1 As shown in FIG. 4, display element 17 may be provided below cover substrate 7, namely above cover substrate 7 in FIG. 1. In this case, the user operates touch panel 100 from the lower surface of lower substrate 14, that is, from above lower substrate 14 in FIG. 4. In touch panel shown in FIG. 4, panel member 30 (see FIG. 2) which is mounted to a housing of the electronic equipment and which is made of transparent or translucent material, such as plastic or glass, is provided above lower substrate 14. The user operates the touch panel 100 from above panel member 30. Even when such a configuration is formed, a similar effect to the present invention can be obtained.

### Second Exemplary Embodiment

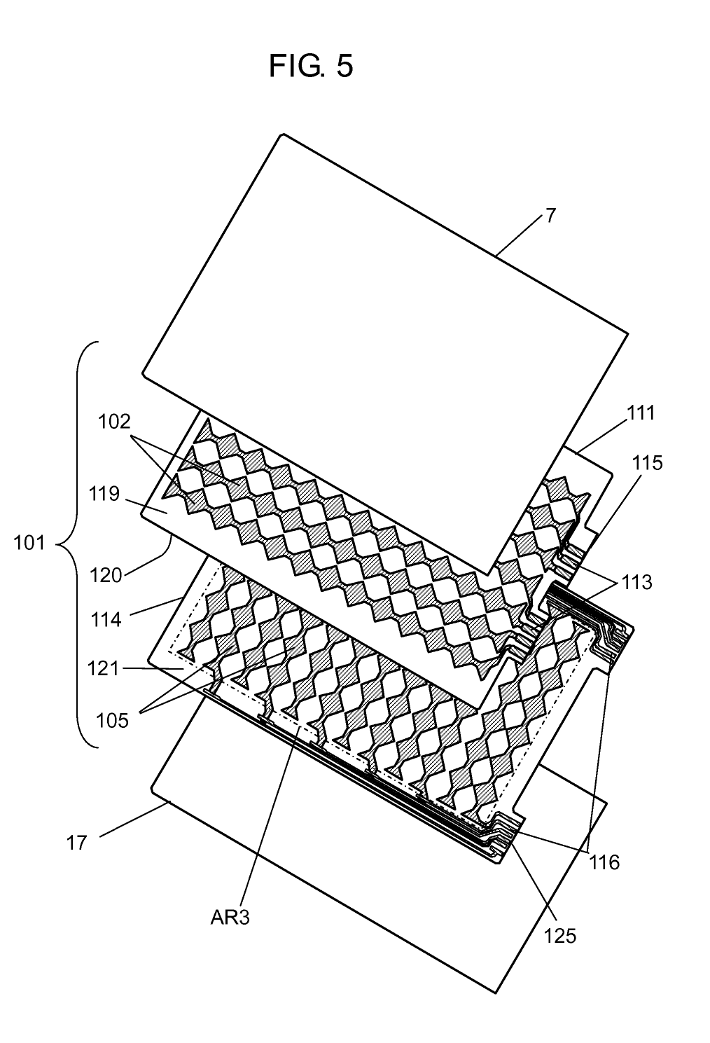

FIG. 5 shows an exploded perspective view of touch panel 101 according to a second exemplary embodiment of the present invention. In addition, the portions having the same configurations as those described in the first exemplary embodiment are provided with the same references.

In FIG. 5, touch panel 101 has lower substrate 114 as a first substrate, plural lower conductive layers 105 as plural first conductive layers, plural lower electrodes 116 as plural first electrodes, cover substrate 7, upper substrate 111 as a second substrate, plural upper conductive layers 102 as plural second conductive layers, and plural upper electrodes 113 as plural second electrodes. Lower substrate 114 has upper surface 121 as a first surface. Upper substrate 111 has lower surface 120 as a second surface and upper surface 119 as a third surface.

The configuration of touch panel 101 is the same as a configuration with a positional relation being reversed to the positional relation of upper substrate 11 and lower substrate 14 in the first exemplary embodiment. Other configurations are similar to those in the first exemplary embodiment.

That is, on upper surface 119 of upper substrate 111, plural upper conductive layers 102 are arrayed in a second direction at predetermined intervals by means of sputtering or the like, and formed extending in a first direction orthogonal to the second direction. Upper substrate 111 has end section 115 in the first direction. One ends of upper electrodes 113 are connected to ends of upper conductive layers 102, and the other ends of upper electrodes 113 are extended to end section 115 of upper substrate 111. Upper electrodes 113 are buried and formed inside thin groove sections provided on upper surface 119 of upper substrate 111.

On upper surface 121 of lower substrate 114, plural lower conductive layers 105 are arrayed in the first direction at predetermined intervals by means of sputtering or the like, and formed extending in the second direction. Lower substrate 114 has end section 125 in the first direction. One ends of plural lower electrodes 116 are connected to end sections of lower conductive layers 105, and the other ends of plural lower electrodes 116 are extended to end section 125 of lower substrate 114. Lower electrodes 116 are extracted to end section 125 through the outer periphery of upper surface 121 of lower substrate 114.

Also in the second exemplary embodiment, the outer periphery of upper surface 121 refers to an area around range AR3 made up of plural lower conductive layers 105, and between range AR3 and the outer edge of upper surface 121. Plural lower electrodes 116 extend from their respective one ends to the other ends in the first direction of the outer periphery of upper surface 121. Plural thin groove sections are formed on the outer periphery of upper surface 121 of lower substrate 114. Plural lower electrodes 116 are buried and formed inside the plural thin groove sections.

In the second exemplary embodiment, the first direction refers to longitudinal directions of upper substrate 111 and lower substrate 114. When respective intervals between plural upper conductive layers 102 arrayed in the second direction and between plural lower conductive layers 105 arrayed in the first direction are made substantially equivalent, as for the number of conductive layers provided on the respective substrates, the number of lower conductive layers 105 is larger than the number of upper conductive layers 102. That is, also as for the numbers of electrodes extracted from the respective conductive layers, the number of lower electrodes 116 is larger than the number of upper electrodes 113. For that reason, plural lower electrodes 116 are arranged at narrower pitches than plural upper electrodes 116 on the outer peripheries.

It is to be noted that the configuration was described above where upper electrode 113 and lower electrodes 116 are respectively buried and formed inside upper substrate 111 and lower substrate 114, but this is not restrictive. The present invention can be implemented even when it is configured such that only one of upper electrodes 113 and lower electrodes 116 are buried and formed inside the substrate and the other electrodes are formed on the upper surface of the substrate by means of printing or the like depending on the number of electrodes and arrangement thereof. For example, plural lower electrodes 116, arranged with narrower pitches, may be buried in lower substrate 114, and plural upper electrodes 113 may not be buried in upper substrate 111. This can eliminate the need for the process step of forming the thin groove sections for burying of upper electrode 113, so as to reduce the number of process steps.

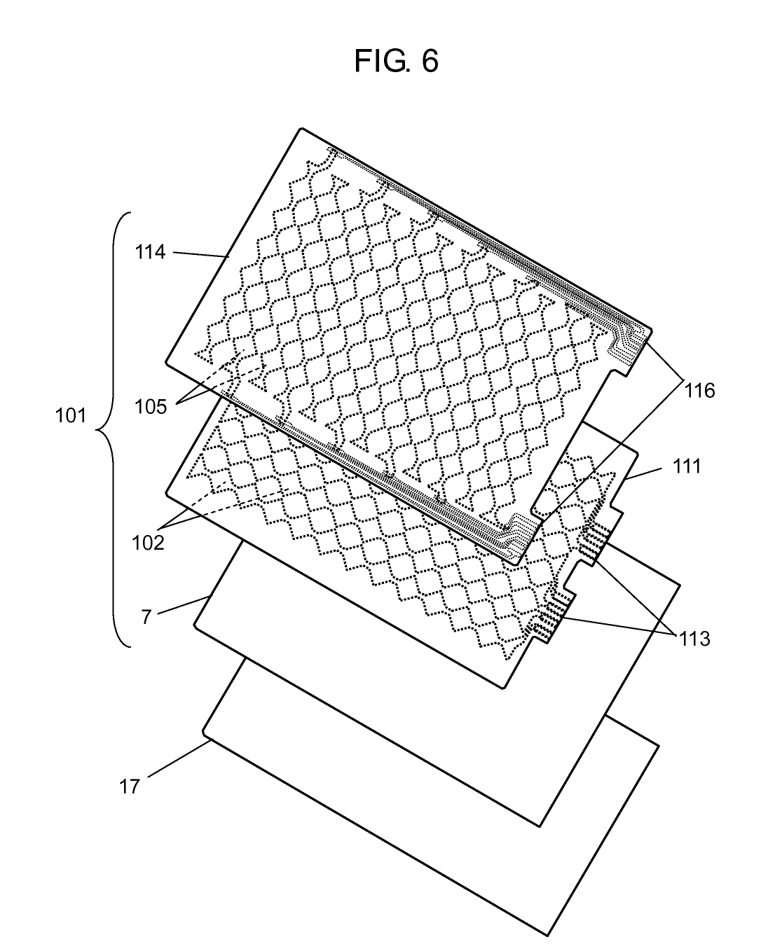

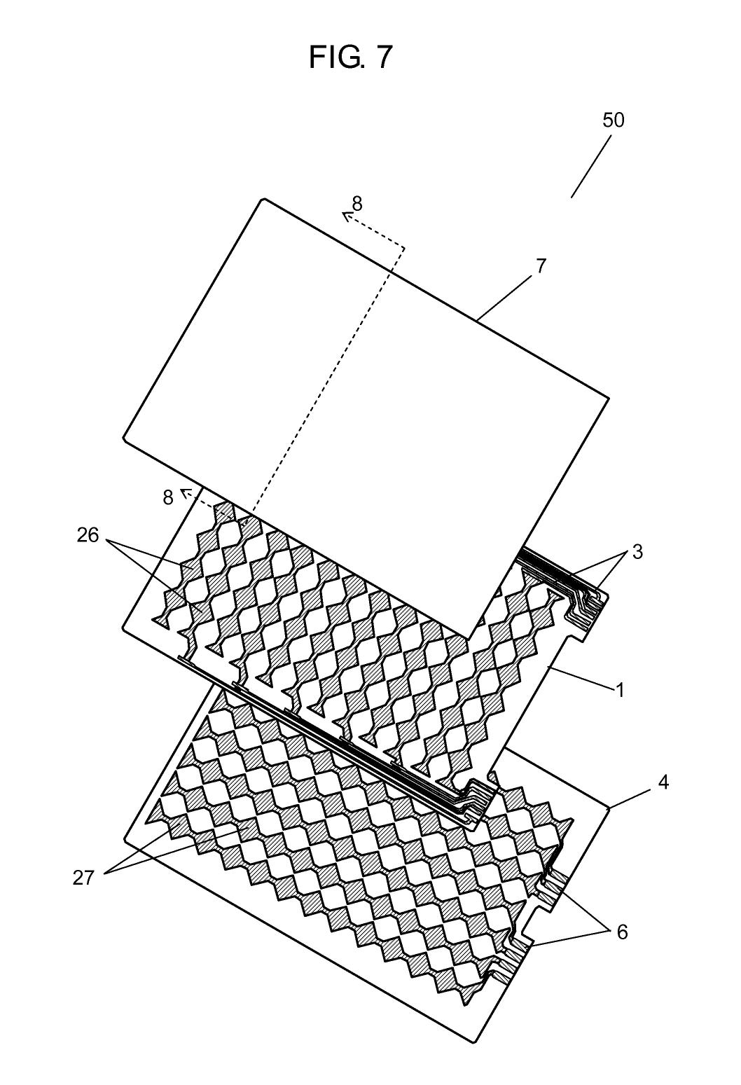

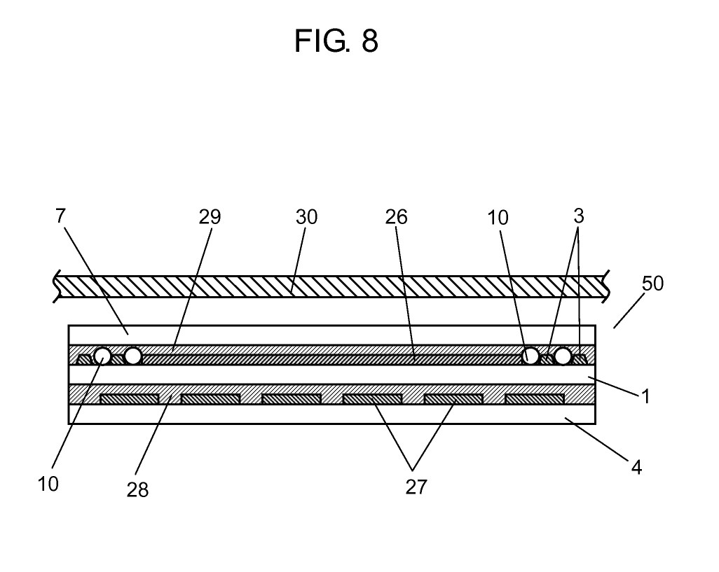

It should be noted that in the second exemplary embodiment, display element 17 may be provided below lower substrate 114 in FIG. 5, and panel member 30 (see FIG. 2) may be provided above cover substrate 7 or as an alternative to cover substrate 7. Further, display element 17 may be provided above cover substrate 7 covering upper surface 119 of upper substrate 111 in FIG. 5. FIG. 6 shows an exploded perspective view of touch panel 101 in the first exemplary embodiment, corresponding to a view from below touch panel 101 shown in FIG. 5. In FIG. 6, display element 17 is provided below cover substrate 7, namely above cover substrate 7 in FIG. 5. In the case of the configuration as thus formed, panel member 30 is provided above lower substrate 114 and the user operates the touch panel 101 from above panel member 30. Even when such a configuration is formed, a similar effect to the present invention can be obtained.

Further, touch panel 101 in the second exemplary embodiment can also be manufactured in a similar manner to the first exemplary embodiment.

In the touch panel according to the present invention, narrow pitching of the electrodes as well as overall size reduction can be sought, and the user can readily view the display element so as to perform a reliable operation, and hence it is useful primarily for operation of electronic equipment.

It should be noted that in the first and second exemplary embodiments, terms indicating directions, such as “upper surface” and “lower surface”, indicate relative directions depending only on relative positional relation of components, such as the upper substrate and lower substrate, of the touch panel, and do not indicate absolute directions, such as a vertical direction.

What is claimed is:

1. A touch panel comprising:
a first substrate;
a plurality of first conductive layers each having a strip shape, the plurality of first conductive layers being provided on a first surface of the first substrate, the plurality of first conductive layers being arrayed in a first direction while extending in a second direction orthogonal to the first direction;
a plurality of first electrodes buried in the first surface of the first substrate, the plurality of first electrodes having one ends connected to the plurality of first conductive layers, respectively;
a second substrate having a second surface opposed to the first surface;
a plurality of second conductive layers each having a strip-shape, the plurality of second conductive layers being opposed to the plurality of first conductive layers, the plurality of second conductive layers being arrayed in the second direction while extending in the first direction; and
a plurality of second electrodes having one ends connected to the plurality of second conductive layers, respectively.

2. The touch panel according to claim 1, further comprising
a first adhesive layer that causes the first surface of the first substrate to adhere to the second surface of the second substrate.

3. The touch panel according to claim 1, wherein
the first substrate has a third surface on the opposite side to the first surface,
the touch panel further comprising a third substrate having a fourth surface opposed to the third surface of the first substrate, and
the plurality of second conductive layers and the plurality of second electrodes are arrayed on the fourth surface of the third substrate.

4. The touch panel according to claim 3, wherein
the plurality of second electrodes are buried in the fourth surface of the third substrate.

5. The touch panel according to claim 4, further comprising:
a first adhesive layer that causes the first surface of the first substrate to adhere to the second surface of the second substrate; and
a second adhesive layer that causes the third surface of the first substrate to adhere to the fourth surface of the third substrate.

6. The touch panel according to claim 1, wherein
the second substrate has a third surface opposite to the second surface, and
the plurality of second conductive layers and the plurality of second electrodes are arrayed on the third surface of the second substrate.

7. The touch panel according to claim 6, wherein
the plurality of second electrodes are buried in the third surface.

8. The touch panel according to claim 6, further comprising
a first adhesive layer that causes the first surface of the first substrate to adhere to the second surface of the second substrate.

9. The touch panel according to claim 1, wherein
the first substrate has an end section located in the first direction,
other ends of the plurality of first electrodes extend to the end section, and
the plurality of first electrodes extend in the first direction from the one ends to the other ends of the plurality of first electrodes on an outer periphery of the first substrate, the outer periphery of the first substrate being located between an outer edge of the first substrate and each of respective ends of the plurality of first conductive layers.

10. The touch panel according to claim 1, wherein
the plurality of first electrodes have exposed surfaces exposed from the first surface of the first substrate, respectively, and
the exposed surfaces of the plurality of first electrodes are flush with the first surface of the first substrate.

11. A method for manufacturing a touch panel, comprising the steps of:
providing a first substrate, a plurality of first conductive layers, and a plurality of first electrodes, the plurality of first conductive layers each having a strip-shape which are arrayed on a first surface of the first substrate, the plurality of first electrodes being buried in the first surface of the first substrate, the plurality of first electrodes having one ends connected to the plurality of first conductive layers, respectively;
providing a second substrate having a second surface; and
causing the first surface to adhere to the second surface after the step of providing the first substrate, the plurality of first conductive layers, and the plurality of first electrodes.
